(19) United States
(12) Patent Application Publication
(10) Pub. No.: US 2016/0128230 A1
(43) Pub. Date: May 5, 2016

(54) DOUBLE-ANGLED FACEPLATE FOR AIR FLOW SYSTEM

(71) Applicant: CISCO TECHNOLOGY, INC., San Jose, CA (US)

(72) Inventors: Mandy Hin Lam, Fremont, CA (US); Hong Tran Huynh, Fremont, CA (US); Vic Hong Chia, Sunnyvale, CA (US); M. Baris Dogruoz, Sunnyvale, CA (US)

(73) Assignee: CISCO TECHNOLOGY, INC., San Jose, CA (US)

(21) Appl. No.: 14/531,615

(22) Filed: Nov. 3, 2014

(51) Int. Cl. H05K 7/20; H05K 7/14

(52) U.S. Cl. CPC H05K 7/20145; H05K 7/20727; H05K 7/1409

(57) ABSTRACT

A faceplate of a line card is provided, and in one example embodiment, includes a top panel including a portion angled downward towards a front side of the faceplate, the angled portion having a plurality of holes, and a front panel disposed on the front side of the faceplate, attached to the angled portion of the top panel on its top side and having a beveled edge at its bottom side, the angled portion of the top panel and the beveled edge of the front panel facilitating an intake area for air flow between the line card and other parallel line cards assembled on a chassis. In specific embodiments, the plurality of holes are arranged in a honeycomb pattern with each hole comprising a Reuleaux hexagon having rounded corners.

### TECHNICAL FIELD

This disclosure relates in general to the field of computer and networking systems and, more particularly, to a double-angled faceplate for an air flow system.

### BACKGROUND

Over the past several years, information technology (IT) has seen a tremendous increase in performance of electronic equipment, coupled with a geometric decrease in floor space to house the equipment. Further, increased performance requirements have led to increased energy use as well, resulting in increased heat dissipation within the crowded floor space. For example, the rate of increase of heat density for communications equipment increased to 28% annually in 1998 from 13% and is projected to continue to increase. As a result, data centers are demanding better thermally managed products that have good computing performance coupled with good thermal performance. Thus, there is a need to design electronic equipment with better thermal characteristics.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1 is a simplified block diagram illustrating an air flow system according to an example embodiment;

FIG. 1A is a simplified block diagram illustrating example details of an embodiment of the air flow system;

FIG. 1B is a simplified block diagram illustrating other example details of an embodiment of the air flow system;

FIG. 2 is a simplified diagram illustrating yet other example details of an embodiment of the air flow system;

FIG. 2A is a simplified diagram illustrating yet other example details of an embodiment of the air flow system;

FIG. 3 is a simplified diagram illustrating yet other example details associated with an embodiment of the air flow system;

FIG. 4 is a simplified diagram illustrating other example details of the air flow system in accordance with an embodiment;

FIG. 4A is a simplified diagram illustrating yet other example details of the air flow system in accordance with an embodiment;

FIG. 5 is a simplified diagram illustrating other example details of the air flow system in accordance with an embodiment;

FIG. 6 is a simplified diagram illustrating other example details of the air flow system in accordance with an embodiment;

FIG. 7 is a simplified diagram illustrating other example details of the air flow system in accordance with an embodiment;

FIG. 8 is a simplified diagram illustrating other example details of the air flow system in accordance with an embodiment; and

FIG. 9 is a simplified flow diagram illustrating example operations that may be associated with an embodiment of the air flow system.

### DETAILED DESCRIPTION OF EXAMPLE EMBODIMENTS

### Overview

A faceplate of a line card is provided, and in one example embodiment, includes a top panel including a portion angled downward towards a front side of the faceplate, the angled portion having a plurality of holes, and a front panel disposed on the front side of the faceplate, attached to the angled portion of the top panel on its top side and having a beveled edge at its bottom side, the angled portion of the top panel and the beveled edge of the front panel facilitating an intake area for air flow between the line card and other parallel line cards assembled on a chassis. In specific embodiments, the plurality of holes are arranged in a honeycomb pattern with each hole comprising a Reuleaux hexagon having rounded corners.

### Example Embodiments

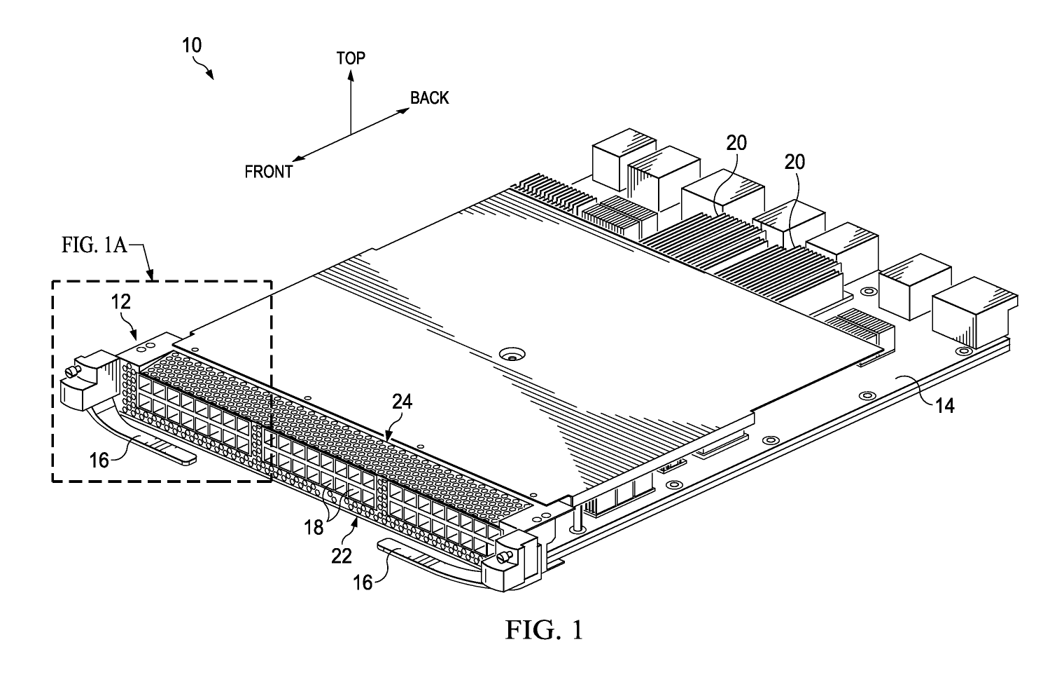

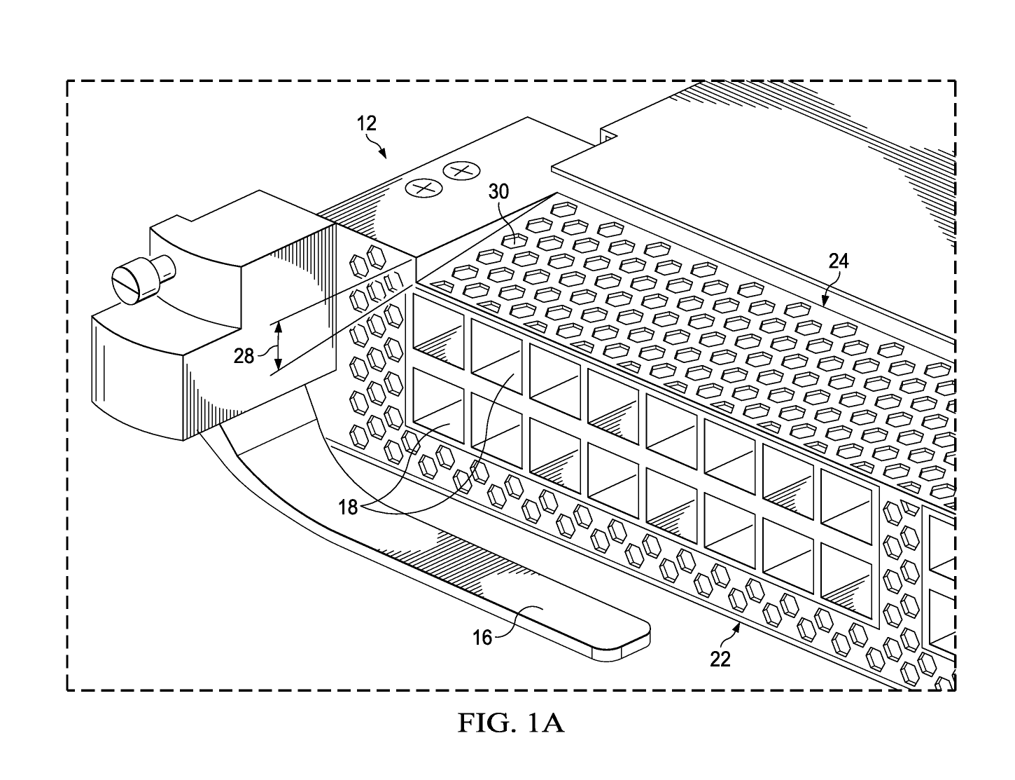

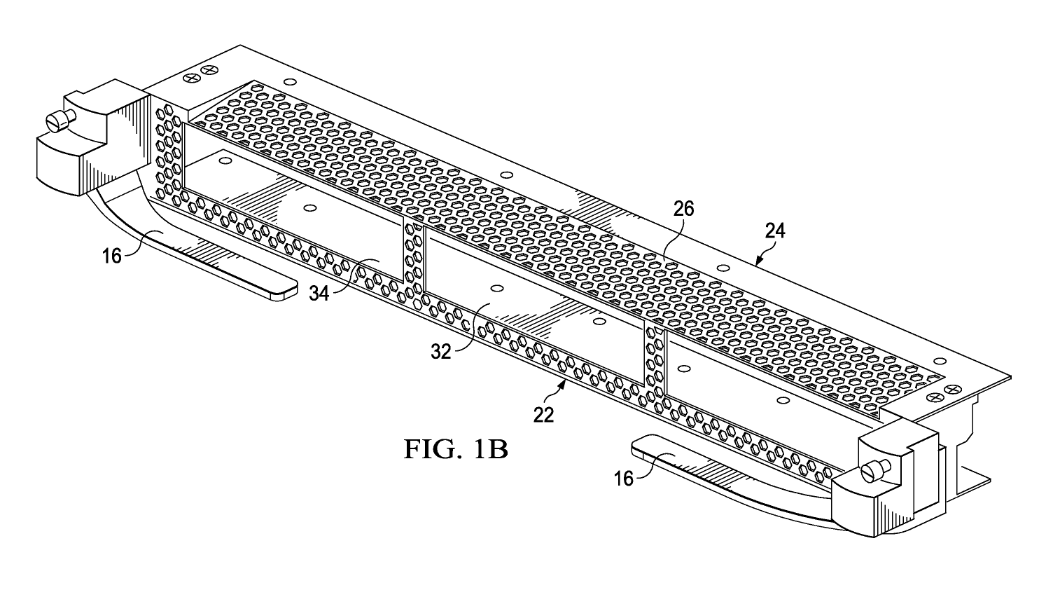

FIG. 1 is a simplified diagram illustrating a perspective view of an air flow system 10 in accordance with one example embodiment. A portion of air flow system 10 is shown in greater detail in FIG. 1A. Air flow system 10 includes a faceplate 12 mounted on a line card 14. As used herein, the term “line card” refers to electronic equipment that includes a modular electronic circuit on printed circuit board to communicate data in a network. “Electronic equipment” can include any equipment (e.g., instrument that performs a task) that includes electronic circuitry, such as computers, switches/routers, line cards, smartphones, motherboards, etc. Faceplate 12 may be mounted using any suitable attachment mechanisms, such as screws, nuts and bolts, adhesives, etc.

In a specific embodiment, line card 14 may be removably attached to a switch (or router) or other similar devices that receive and forward packets in the network. For example, line card 14 may include ejector levers 16 that can be used to plug line card 14 into a chassis of the switch (or router). In specific embodiments, line card 14 may include a plurality of port holes 18 (e.g., ports serve as entry and exit points of data in the switch), each port hole 18 indicating an opening to which a networking cable (e.g., Ethernet cable, fiber optic cable, etc.) can be plugged using a suitable connector (e.g., RJ45 connector, SFP connector, etc.).

Line card 14 may include a plurality of heat generating components 20. Heat generating components 20 may include electrical circuits, for example, power supplies, batteries, signal processors and other semiconductor chips, resistors, memory elements, etc. According to various embodiments, removable faceplate 12 can improve airflow and thermal performance in air flow system 10.

In various embodiments, faceplate 12 includes a double-angled panel configuration that can provide optimal electromagnetic interference (EMI) performance and larger air flow capacity than conventional faceplates. Faceplate 12 includes a front panel 22 disposed on its front side, and a top panel 24 disposed on its top side. Top panel 24 includes an angled portion 26 that angles downward away from a horizontal plane towards front panel 22 by an angle 28. In an example embodiment, the rise (e.g., vertical distance) of angled portion 26 may be 0.253″.

Angled portion 26 includes holes 30 that may be arranged in a pattern. In an example embodiment, holes 30 may be arranged in a honeycomb pattern. Front panel 22 may include openings 32 to accommodate port holes 18 of line card 14 and a bevel (not shown) towards a bottom side of faceplate 12. In various embodiments, the bevel may extend for the entire width of front panel 22 on its front face. Ejector levers 16 may be disposed on the left and right sides of faceplate 12. A substantially flat panel 34 may be disposed on a bottom side of faceplate 12. After assembly to line card 14, line card 14 may be disposed at a back side of faceplate 12. Note that with respect to air flow system 10, a front side denotes a direction towards faceplate 12 from a hypothetical center of line card 14; a back side denotes an opposite direction; and a top side denotes a direction perpendicular to surface of line card 14, as indicated in the FIGURE.

In various embodiments, faceplate 12 may be manufactured using existing manufacturing processes, such as extrusion. In a general sense, extrusion is a generally known manufacturing process in which a material is pushed or drawn through a die of a desired cross-section. Extrusion may be continuous (e.g., producing long material of intricate shape) or semi-continuous (e.g., producing many pieces, each of intricate shape). The extrusion process can be done with hot or cold material. In various embodiments, the material used for faceplate 12 may comprise aluminum. Note that any suitable thermally conducting material can be used within the broad scope of the embodiments.

In addition, faceplate 12 may provide a double-angled cosmetic look, which provides a unique identifier thereof, when assembled in a switch chassis with other line cards adjacent to it. For example, the bevel on front panel 22 and angle 28 of another top panel of an adjacent line card on a switch chassis can increase an air intake area between line card 14 and the adjacent line card. Likewise, angle 28 of angled portion 26 of top panel 24 with the bevel of another front panel of another adjacent line card on the switch chassis can increase the air intake area between line card 14 and the another adjacent line card.

For purposes of illustrating the techniques of air flow system 10, it is important to understand the constraints in a given system such as the system shown in FIG. 1. The following foundational information may be viewed as a basis from which the present disclosure may be properly explained. Such information is offered earnestly for purposes of explanation only and, accordingly, should not be construed in any way to limit the broad scope of the present disclosure and its potential applications.

Most modern communications equipment includes heat generating electronic components that have to be cooled to enable them to perform effectively. Typically, the electronic components are cooled using air that is forced into the equipment chassis and made to flow over the electronic components. In data center environments with large number of electronic components, thermal management can be a challenge. Some data centers utilize a hot aisle/cold aisle layout design for server racks and other computing equipment to conserve energy and lower cooling costs by managing air flow effectively.

In its simplest form, hot aisle/cold aisle data center design involves lining up server racks in alternating rows with cold air intakes facing one way and hot air exhausts facing another way. The rows composed of rack fronts are called cold aisles. Typically, cold aisles face air conditioner output ducts. The rows, into which heated exhausts pour, are called hot aisles. Typically, hot aisles face air conditioner return ducts. Cool air thus enters at the front, and hot air exits at the back.

Equipment used in such hot aisle/cold aisle data centers may have front-to-back airflow cooling. For example, in a switch comprising a plurality of line cards, the air enters at a front panel faceplate of each individual line card (e.g., front panel being perpendicular to the length of the line card), passes through a mid-plane of the line card, and exits at the back of the switch chassis. The front panel can include perforations, which permit air to enter the chassis. The perforation area can affect board-level (e.g., at the line card level) and system-level (e.g., at the switch chassis level) cooling. However, port density of the line-cards is already quite high, and expected to increase in the future. The increasing number of ports on the faceplate and the limited total exposed area of the faceplate present a challenge in configuring the perforations on the front panel faceplate. Moreover, the power dissipation and cooling demands are increased proportional to the port density. However, with the increased port density, the perforation area is reduced. Thus, the cooling capacity of the line card is reduced.

Moreover, EMI shielding is a consideration in such thermal management systems. EMI refers to disturbance that affects an electrical circuit due to either electromagnetic induction or electromagnetic radiation emitted from an external source. The disturbance may interrupt, obstruct, or otherwise degrade the effective performance of the electrical circuit. The degradation can range from a simple loss of quality data to a total data loss. In general, metallic materials can block the magnetic field that gives rise to EMI, thereby providing effective EMI shielding. The amount of shielding depends upon the material used, its thickness, the size of the shielded volume and the frequency of the fields of interest and the size, shape and orientation of apertures in the shield to an incident electromagnetic field.

Typical materials used for electromagnetic shielding include sheet metal, metal screen, and metal foam. Any holes in the shield should be significantly smaller than the wavelength of the radiation that is being kept out, or the shield may not effectively approximate an unbroken conducting surface. For most high frequency applications, aluminum can be a suitable material choice for the EMI shield; for low frequency applications, steel may be more suitable.

A typical choice for the EMI shield where air flow is also a consideration is an EMI venting screen, which includes a sheet of conductive material having holes in a honeycomb pattern. The shielded honeycomb EMI venting screen may be based on at least three criteria: attenuation (e.g., EMI shielding ability), air flow (e.g., how much static pressure drop is introduced into the system), and mounting (e.g., attachment method). EMI shielding is improved with more conductive surface and less number of openings; on the other hand, air flow is improved with higher number of openings. Thus, configuration of a suitable EMI venting screen may involve a tradeoff between EMI shielding and air flow.

Air flow system 10 is configured to address these issues (and others) in offering faceplate 12 that can improve thermal performance (among other advantages). Embodiments of air flow system 10 can increase heat transfer and maintain (or enhance) EMI shielding performance. Air flow system 10 can be configured to require no extra space or additional area than already used by line card 14.

In various embodiments, faceplate 12 includes top panel 24 having a portion 26 angled downward at an angle 28 towards a front side of faceplate 12, angled portion 26 having a plurality of holes 30. Faceplate 12 also include a front panel 22 disposed on the front side of faceplate 12, attached to angled portion 26 at its top side and having a beveled edge at its bottom side. In various embodiments, angled portion 26 of top panel 24 and the beveled edge of front panel 22 facilitate an intake area for air flow between line card 14 and other parallel line cards assembled on a chassis. In some embodiments, angled portion 26 of top panel 24 is thick to facilitate EMI shielding performance. Line card 14 is disposed towards a backside of faceplate 12, between top panel 24 and bottom panel 34. In some embodiments, line card 14 is removably attached to faceplate 12, for example, using suitable screws or nuts and bolts.

In some embodiments, a plurality of line cards may be assembled parallel to each other in a chassis of a switch, the line cards being removably attached and electrically connected to the switch. Each line card 14 includes faceplate 12 comprising top panel 24 with angled portion 26 having plurality of holes 30; front panel 22 attached to angled portion 26 on its top side and having a beveled edge on its bottom side; and bottom panel 34 disposed on the bottom of faceplate 12 and attached to front panel 22 along the beveled edge. In various embodiments, a channel for air flow is disposed between top panel 24 of the faceplate any one line card and bottom panel 34 of another faceplate of the adjacent line card. In particular embodiments, angled portion 26 of top panel 24 of the faceplate of any one line card and the beveled edge of front panel 22 of another faceplate of the adjacent line card facilitates an intake area of the channel that is greatest at the front of the faceplates.

Although faceplate 12 is illustrated and described with reference to line card 14, it may be noted that faceplate 12 may be installed in other devices (e.g., computers, laptops, etc.) where thermal management, EMI shielding, and small form factor (e.g., reduced surface area to place air flow vents) can be particular considerations in design choices.

Note that the numerical and letter designations assigned to the elements of FIG. 1 do not connote any type of hierarchy; the designations are arbitrary and have been used for purposes of teaching only. Such designations should not be construed in any way to limit their capabilities, functionalities, or applications in the potential environments that may benefit from the features of air flow system 10. It should be understood that the air flow system 10 shown in FIG. 1 is simplified for ease of illustration.

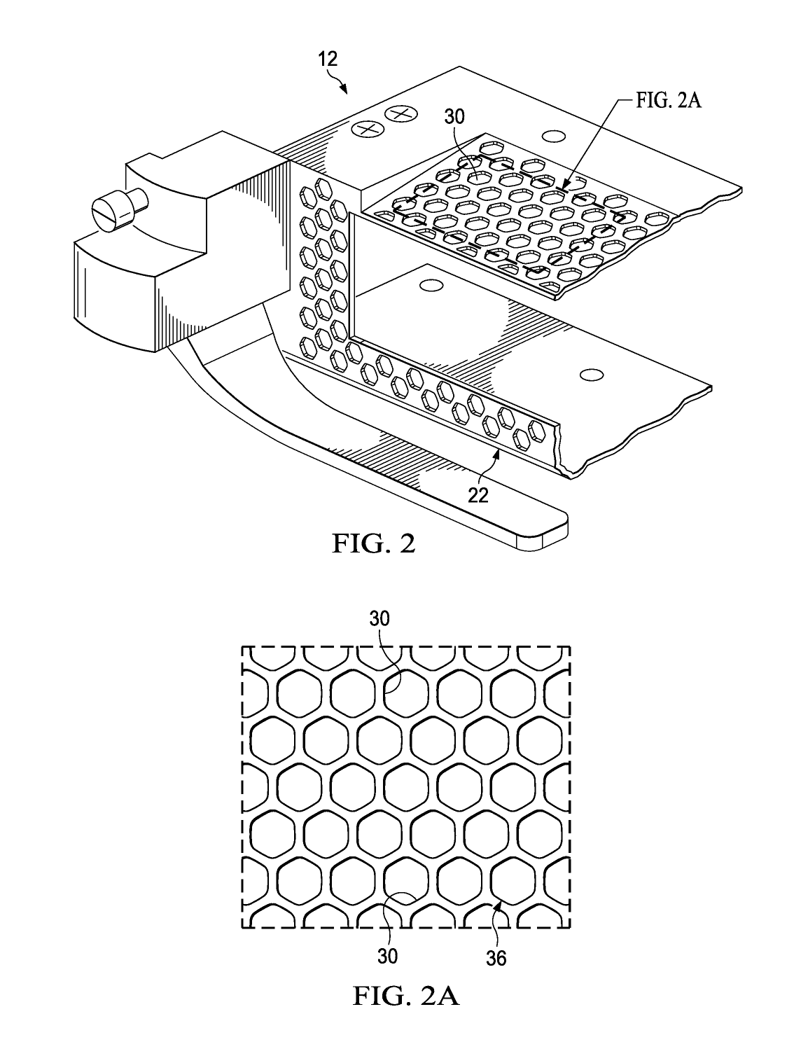

FIG. 2 is a simplified diagram showing example details of a honeycomb structure of angled portion 26 of top panel 24 of faceplate 12. Holes 30 may comprise shape 36 disposed in a honeycomb pattern. In an example embodiment, shape 36 comprises a Reuleaux hexagon (e.g., hexagon with curved edges, such as arcs) with rounded corners (e.g., not sharp corners), as indicated in FIG. 2A. The curved edges and corners of shape 36 can facilitate a larger hole than is possible with straight edges and corners of traditional hexagonal patterns. In some embodiments, shape 36 may have straight edges, as in a regular hexagon, but have rounded corners, instead of sharp corners. Top panel 22 may be thicker than conventional panels for better EMI shielding performance. Holes 30 may be larger than in conventional faceplates for better air flow characteristics.

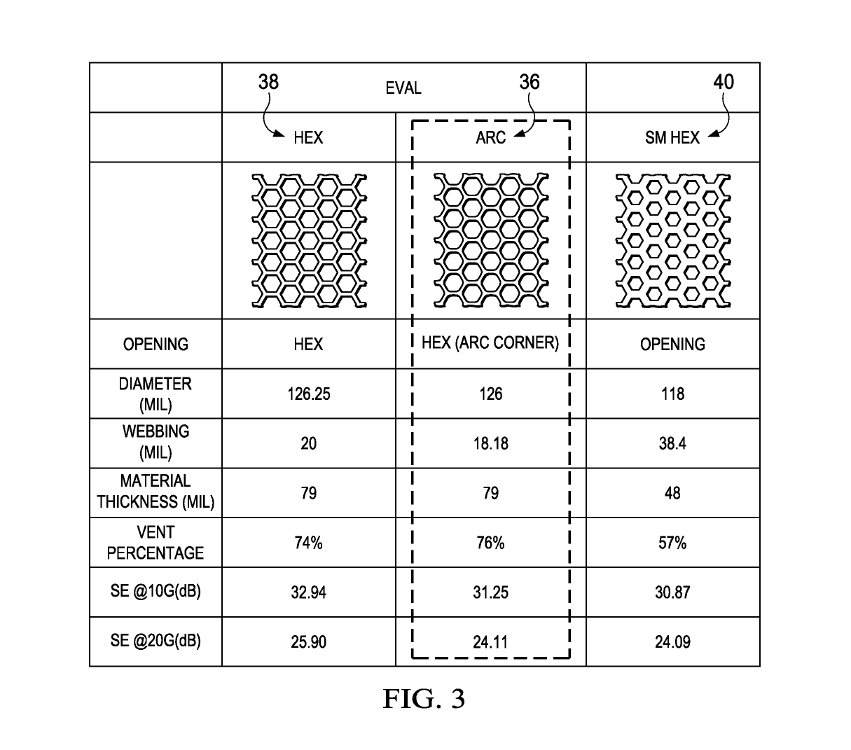

FIG. 3 is a simplified diagram illustrating example details of simulated evaluation results according to an embodiment of air flow system 10. Air flow performance of shape 36 (e.g., Reuleaux hexagon with arc shaped edges instead of straight edges and rounded corners) may be compared with a regular hexagonal shape 38 and a smaller hexagon 40 as used in conventional line cards. With shape 36 comprising arcs instead of straight edges along the sides of the Reuleaux hexagon and rounded corners, the amount of webbing material (18.18 mil) may be lower as compared to conventional shape 40 (38.4 mil), or regular hexagon 38 (20 mil). Moreover, increased vent size (76%) may be obtained with shape 36, as compared to 57% with conventional shape 40 and 74% with regular hexagon shape 38.

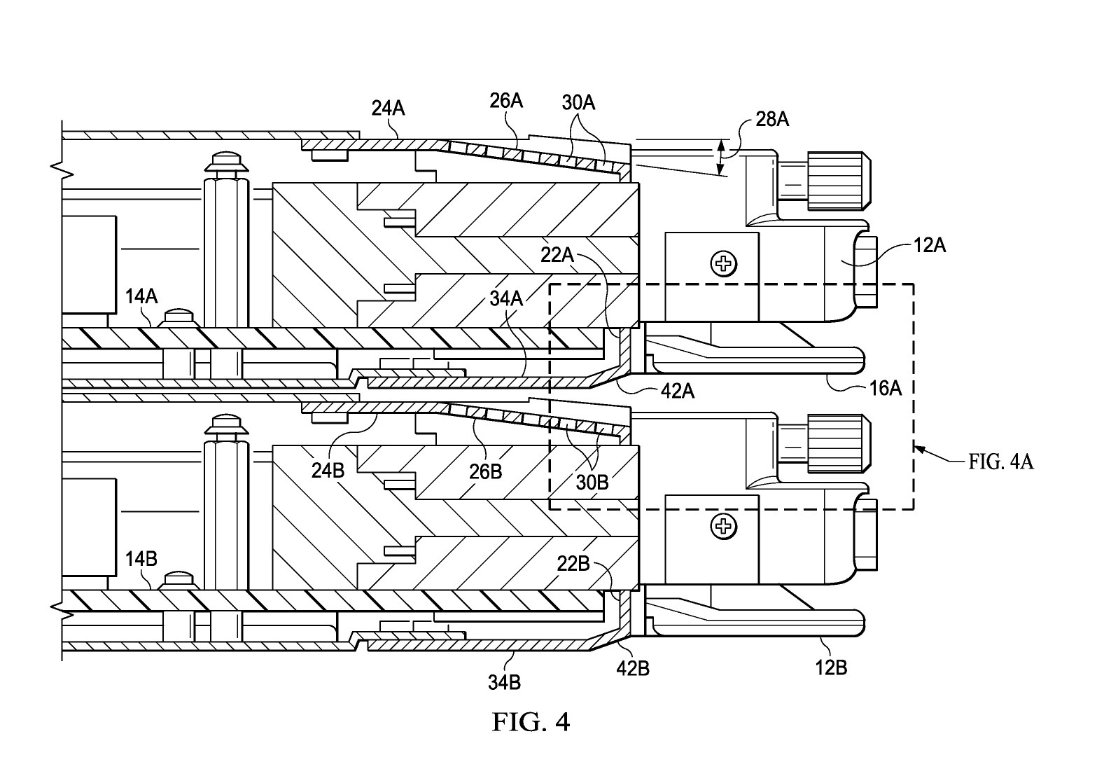

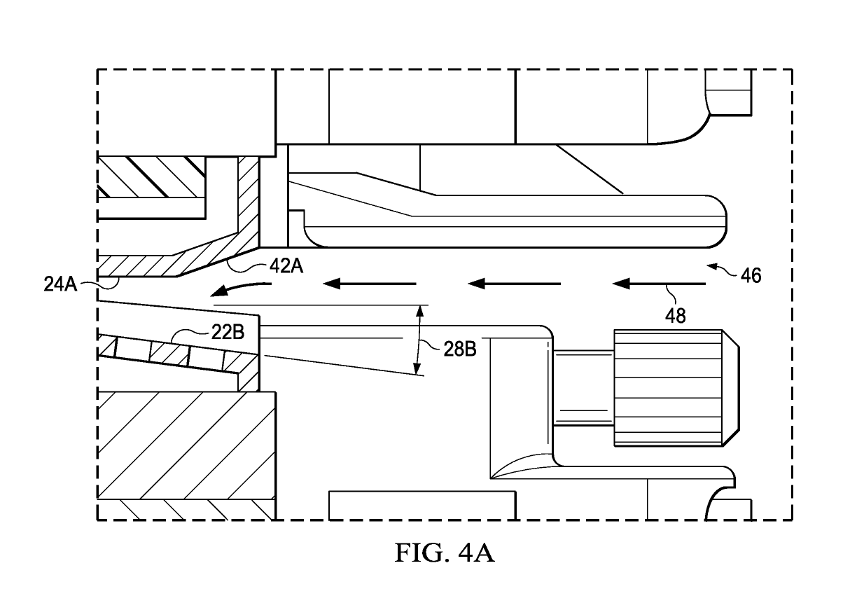

FIG. 4 is a simplified diagram illustrating example details of an embodiment of air flow system 10. Two line cards 14A and 14B may be arranged in a chassis of a switch (or router) (not shown) spaced from each other vertically (or horizontally). In an example configuration shown in the FIG. 4, line card 14A is disposed on top of line card 14B. Line card 14A may be attached to corresponding faceplate 12A; line card 14B may be attached to corresponding faceplate 12B. In the example configuration, top panel 24B of faceplate 12B may be adjacent to bottom panel 34A of faceplate 12A.

Front panels 22A and 22B of respective faceplates 12A and 12B may include respective bevels (e.g., chamfer) 42A and 42B. In an example embodiment, rise (e.g., vertical distance from top of bevel to the bottom) of bevels 42A and 42B may be 0.084″. In the assembled configuration, rises of bevel 34A (e.g., 0.084″) and angled portion 26B (e.g., 0.253″) may provide an additional vertical spacing (e.g., 0.337″) at the front side of faceplates 12A and 12B and between line cards 14A and 14B. The additional vertical spacing may result in a larger air intake area 44 as air is pushed from the front of faceplates 12A and 12B towards the back.

As shown in greater detail in FIG. 4B, angle 28B of angled portion 26B of top panel 24B of faceplate 12B and bevel 36A of front panel 22A of faceplate 12A can create large intake area 44 for a channel 46 between line cards 14A and 14B that can facilitate greater air flow over line card 14B and under line card 14A. Intake area 44 may be largest cross-sectional area of channel 46 due to angled portion 26B of top panel 24 of faceplate 12B and beveled edge 42A of front panel 22A of faceplate 12A. The increased intake area from the angled vent can reduce pressure drop, reduce card impedance, increase slot air flow and lower acoustic noises (e.g., fan works quitter at lower pressure drop conditions). In some example embodiments, a 30% larger intake area 44 can provide 20% air flow improvement over an alternate configuration without the angled portion of the top panel and beveled edge of the front panel. According to various embodiments, channel 46 may be disposed above top panel 24B of faceplate 12B and under bottom panel 34A of top faceplate 12A throughout the lengths of line cards 14A and 14B, for example, from a front of the chassis to the back of the chassis.

According to various embodiments, air may be guided along channel 46, through holes 30B of angled portion 26B of top panel 22B of bottom faceplate 12B, to one or more heat generating components 20 on line card 14B. Air may be guided in a direction indicated generally by arrows 48 as shown in FIG. 4A. The air may eventually exit line card 14B at a back (or side portion), thus enabling a front-to-back air cooling system. In various embodiments, a fan (not shown) operating behind line cards 14A and 14B may pull in air at the front and push it out the back.

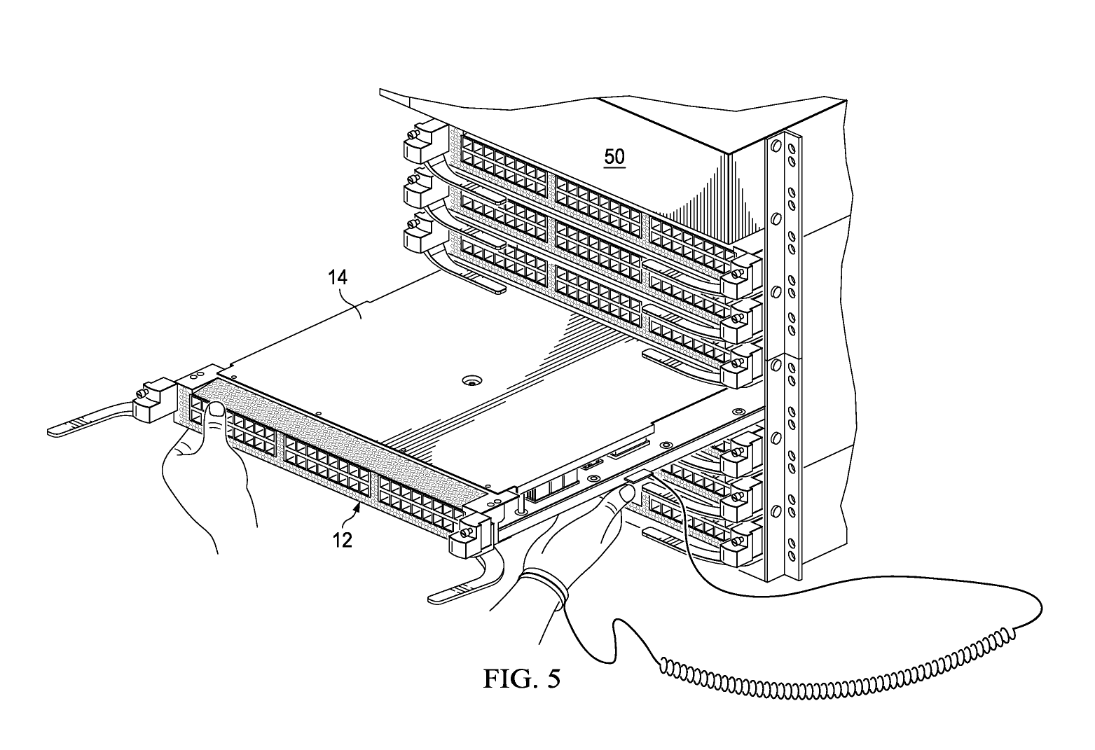

FIG. 5 is a simplified diagram illustrating line card 14 in a switch chassis 50 according to an example configuration. In some embodiments, line card 14 may be placed horizontally and guided out of or into a slot in switch chassis 50. To remove or insert line card 14 from switch chassis 50, captive screws on faceplate 12 may be loosened, ejector levers 16 pivoted to unlock or lock line card 14, and line card 14 may be slid out of or into switch chassis 50. A plurality of line cards may be arranged one on top of the other, spaced apart vertically from each other. The double-angled feature of faceplates 12 of the respective line cards may allow larger air flow between the line cards.

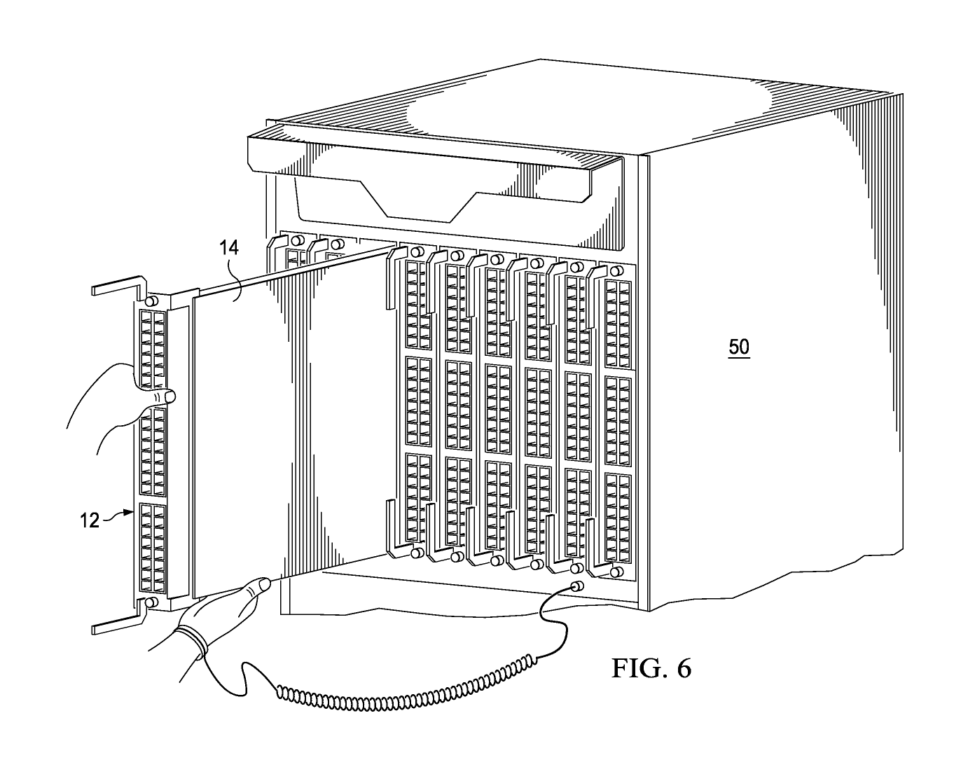

FIG. 6 is a simplified diagram illustrating line card 14 in switch chassis 50 according to another example configuration. In some embodiments, line card 14 may be placed vertically and guided out of or into a slot in switch chassis 50. To remove or insert line card 14 from switch chassis 50, captive screws on faceplate 12 may be loosened, ejector levers 16 pivoted to unlock or lock line card 14, and line card 14 may be slid out of or into switch chassis 50. A plurality of line cards may be arranged side by side, spaced apart horizontally from each other. The double-angled feature of faceplates 12 of the respective line cards may allow larger air flow between the line cards.

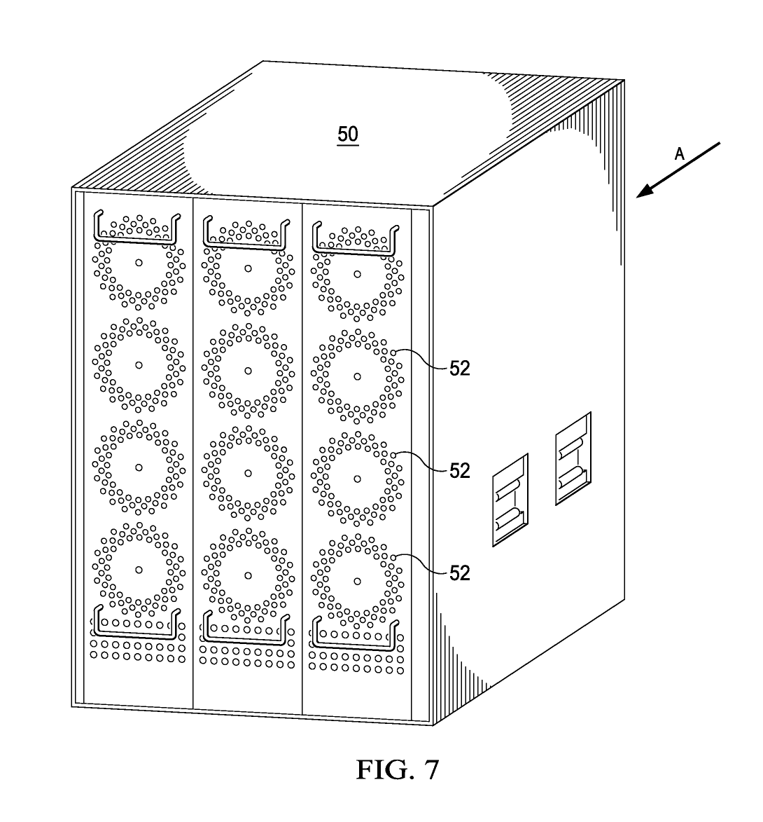

FIG. 7 is a simplified diagram illustrating an example air flow of a switch according to an example configuration. In various embodiments, switch chassis 50 may include one or more fans 52 (shown via holes behind the fans) behind line cards 14 in switch chassis 50. During operation, fans 52 may pull in air from a front of switch chassis 50, as indicated by arrow A. Air may flow through channel 46, and through openings 30 in faceplate 12 of each line card 14, over heat generating components 20 of each line card 14, and exit out of a back of switch chassis 50.

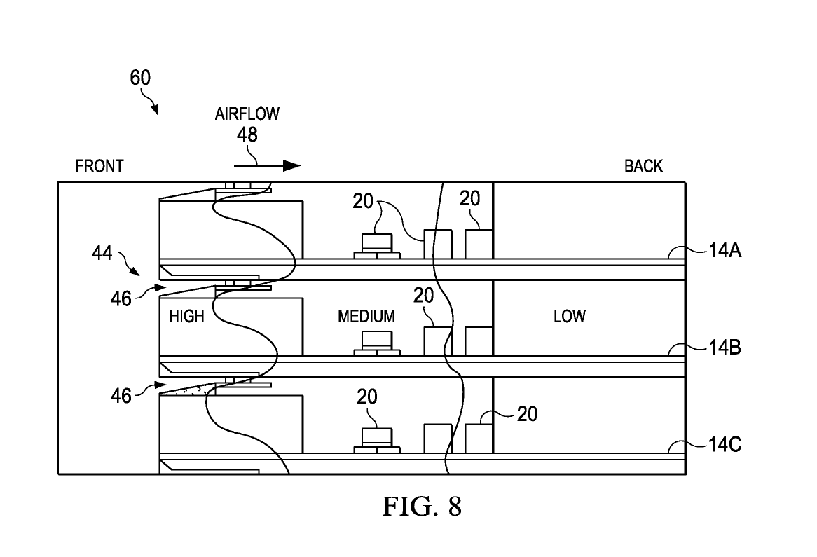

FIG. 8 is a simplified diagram illustrating pressure plot 60 (in inches of water) across a plurality of line cards 14A, 14B and 14C according to an embodiment of air flow system 10. In the simulation results, the pressure is highest towards the front of system 10 and decreases towards the back. Air enters from the front and flows towards the back, as generally indicated by arrow 48. Intake area 44 being large, larger air flow through channel 46 may be achieved, potentially increasing heat transfer from heat generating components 20.

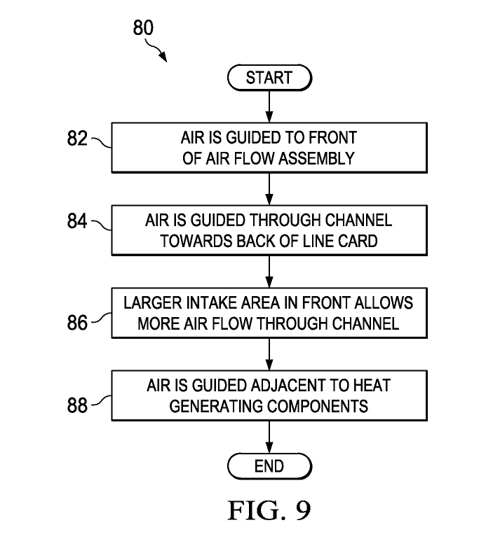

FIG. 9 is a simplified flow diagram illustrating example operations 80 that may be associated with an embodiment of air flow system 10. At 82, air may be guided to the front of faceplate 12. At 84, air is guided through channel 46 towards back of line card 14. At 86, larger intake area 44 at front of channel 46 allows more air flow through channel 46. At 88, air is guided adjacent (e.g., near, over, around, etc.) heat generating components 20, for example, facilitating heat transfer.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

It is imperative to note that countless possible design configurations can be used to achieve the operational objectives outlined here. Accordingly, the associated infrastructure of air flow system 10 may have a myriad of substitute arrangements, design choices, device possibilities, hardware configurations, equipment options, etc. It is also important to note that the operations and steps described with reference to the preceding FIGURES illustrate only some of the possible scenarios that may be executed by, or within, the system. Some of these operations may be deleted or removed where appropriate, or these steps may be modified or changed considerably without departing from the scope of the discussed concepts.

In addition, the timing of these operations may be altered considerably and still achieve the results taught in this disclosure. The preceding operational flows have been offered for purposes of example and discussion. Substantial flexibility is provided by the system in that any suitable arrangements, chronologies, configurations, and timing mechanisms may be provided without departing from the teachings of the discussed concepts.

Although the present disclosure has been described in detail with reference to particular arrangements and configurations, these example configurations and arrangements may be changed significantly without departing from the scope of the present disclosure. For example, although the present disclosure has been described with reference to a line card, air flow system 10 may be applicable to other devices where higher air flow may be desired. In other embodiments, considerations other than EMI shielding or air flow may drive a similar configuration. All such scenarios are included within the broad scope of the embodiments disclosed herein.

In various embodiments, the elements of air flow system 10 may be composed of any kind of materials, including metal, plastic, wood, fiber glass, semiconductors, etc., or a combination thereof. In a specific embodiment, faceplate 12 may be composed of metallic materials, such as aluminum or steel. While metallic materials may be applicable to considerations of EMI, in devices where EMI is not a consideration, any suitable material, including non-metallic materials may be used.

While screws and similar attachment mechanisms are illustrated in the FIGURES, it may be noted that any kind of attachment mechanisms may be used, including clips, latches, grooves, or other mating and connection devices. In embodiments where the components are removably attached to each other, the attachment mechanisms may be appropriately configured to enable the components to be removed as needed. In other embodiments, where the components are permanently attached to each other, the attachment mechanisms may be appropriately configured to disable separation between the components without destroying them. Examples of such permanent attachment mechanisms include welding, brazing, gluing, etc.

In terms of the dimensions of the articles discussed herein any suitable length, width, and depth (or height) may be used and can be based on particular end user needs, or specific elements to be addressed by the apparatus (or the system in which it resides). It is imperative to note that all of the specifications and relationships outlined herein (e.g., height, width, length, hole diameter, number of holes per unit of area, etc.) have only been offered for purposes of example and teaching only. Each of these data may be varied considerably without departing from the spirit of the present disclosure, or the scope of the appended claims. The specifications apply only to one non-limiting example and, accordingly, should be construed as such. Along similar lines, the materials used in constructing the articles can be varied considerably, while remaining within the scope of the present disclosure.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

What is claimed is:

1. A faceplate of a line card, comprising:
a top panel including a portion angled downward towards a front side of the faceplate, the angled portion having a plurality of holes; and
a front panel disposed on the front side of the faceplate, attached to the angled portion of the top panel on its top side and having a beveled edge at its bottom side, wherein the angled portion of the top panel and the beveled edge of the front panel facilitate an intake area for air flow between the line card and other parallel line cards assembled on a chassis.

2. The faceplate of claim 1, wherein the plurality of holes are arranged in a honeycomb pattern with each hole comprising a Reuleaux hexagon having rounded corners.

3. The faceplate of claim 1, wherein the plurality of holes are arranged in a honeycomb pattern with each hole comprising a regular hexagon having rounded corners.

4. The faceplate of claim 1, wherein the angled portion of the top panel is thick to enhance electromagnetic interference (EMI) shielding.

5. The faceplate of claim 1, wherein the front panel includes openings configured to accommodate ports on the line card.

6. The faceplate of claim 1, wherein the faceplate further comprises:
ejector levers on either side of the faceplate; and
a bottom panel attached to the beveled edge of the front panel.

7. The faceplate of claim 6, wherein the line card is disposed towards a backside of the faceplate, between the top panel and the bottom panel.

8. The faceplate of claim 1, wherein the faceplate is removably attached to the line card.

9. The faceplate of claim 1, wherein the faceplate is manufactured using extrusion.

10. An apparatus comprising:
a switch;
a fan disposed towards a back side of the apparatus; and
a plurality of line cards removably attached and electrically connected to the switch, wherein the line cards are disposed parallel to each other, wherein each line card includes a faceplate comprising:
a top panel including a portion angled downward towards a front side of the faceplate, the angled portion having a plurality of holes;
a front panel disposed on the front side of the faceplate, attached to the angled portion of the top panel on its top side and having a beveled edge at its bottom side; and
a bottom panel disposed on a bottom side of the faceplate, attached to the front panel along the beveled edge.

11. The apparatus of claim 10, wherein a channel for air flow is disposed between the top panel of the faceplate of any one line card and the bottom panel of the faceplate of an adjacent line card.

12. The apparatus of claim 11, wherein the angled portion of the top panel of the faceplate of any one line card and the beveled edge of the front panel of another faceplate of the adjacent line card facilitates an intake area of the channel that is greatest at the front of the faceplates.

13. The apparatus of claim 11, wherein the fan is disposed behind the line cards towards a back of the apparatus, wherein when the fan operates, air is pulled in through the channel from the front of the faceplates and is forced over one or more heat generating components on each line card.

14. The apparatus of claim 11, wherein the plurality of holes are arranged in a honeycomb pattern with each hole comprising a Reuleaux hexagon having rounded corners.

15. The apparatus of claim 10, wherein the front panel includes a plurality of openings to accommodate ports on each line card.

16. A method, comprising:
guiding air through a channel formed in a space between two line cards disposed adjacent and parallel to each other in a chassis of an electronic equipment, each line card removably attached to a faceplate, wherein the faceplate comprises:
a top panel including a portion angled downward towards a front side of the faceplate, the angled portion having a plurality of holes;
a front panel disposed on the front side of the faceplate, attached to the angled portion of the top panel on its top side and having a beveled edge at its bottom side; and
a bottom panel disposed on a bottom side of the faceplate, attached to the front panel along the beveled edge;
guiding the air through the plurality of holes in the angled portion of the top panel of each faceplate; and
guiding the air adjacent to heat generating components on each line card.

17. The method of claim 16, wherein the angled portion of the top panel of the faceplate of one line card and the beveled edge of the front panel of another faceplate of the adjacent line card facilitates an intake area of the channel that is greatest at the front of the faceplates.

18. The method of claim 16, wherein the air is guided from the front of the faceplates towards a back of the chassis.

19. The method of claim 16, wherein the air is guided through the channel by a fan.

20. The method of claim 16, wherein the faceplate has a plurality of openings to accommodate ports in the line card.
